(19) United States
(12) Patent Application Publication
(10) Pub. No.: US 2024/0194771 A1
(43) Pub. Date: Jun. 13, 2024

(54) SEMICONDUCTOR DEVICE

(71) Applicant: FUJI ELECTRIC CO., LTD., Kanagawa (JP)

(72) Inventor: Takayuki KOBAYASHI, Matsumoto-city (JP)

(21) Appl. No.: 18/492,783

(22) Filed: Oct. 24, 2023

(30) Foreign Application Priority Data
Dec. 12, 2022 (JP) 2022-198249

(51) Int. Cl. H01L 29/739; H01L 29/10

(52) U.S. Cl. CPC H01L 29/7397; H01L 29/1095

(57) ABSTRACT

Provided is a semiconductor device comprising a transistor portion and a diode portion, wherein the diode portion includes: a plurality of trench portions provided in a semiconductor substrate; a drift region of a first conductivity type provided in the semiconductor substrate; an anode region of a second conductivity type provided above the drift region; a second contact region of the second conductivity type provided in a front surface of the semiconductor substrate above the anode region and having a higher doping concentration than the anode region; and a carrier stop region of the first conductivity type provided below the second contact region and having a higher doping concentration than the drift region, wherein carrier stop regions including the carrier stop region are discretely provided in a trench extending direction.

The contents of the following Japanese patent application(s) are incorporated herein by reference:
No. 2022-198249 filed in JP on Dec. 12, 2022

### BACKGROUND

### 1. Technical Field

The present invention relates to a semiconductor device.

### 2. Related Art

Patent Document 1 describes a semiconductor device in which an IGBT region and a diode region are provided on the same semiconductor substrate.

### PRIOR ART DOCUMENT

### Patent Document

Patent Document 1: Japanese Patent Application Publication No. 2013-26534

### BRIEF DESCRIPTION OF THE DRAWINGS

FIG. 1A shows an example of a top view of a semiconductor device 100 according to Example Embodiment 1.

FIG. 1B shows an example of a cross section a-a′ in FIG. 1A.

FIG. 1C shows an example of a cross section b-b′ in FIG. 1A.

FIG. 2A shows an example of a top view of a semiconductor device 100 according to Example Embodiment 2.

FIG. 2B shows an example of a cross section a-a′ in FIG. 2A.

FIG. 2C shows an example of a cross section b-b′ in FIG. 2A.

FIG. 3A shows an example of a top view of a semiconductor device 100 according to Example Embodiment 3.

FIG. 3B shows an example of a cross section a-a′ in FIG. 3A.

FIG. 3C shows an example of a cross section b-b′ in FIG. 3A.

FIG. 4A shows an example of a top view of a semiconductor device 100 according to Example Embodiment 4.

FIG. 4B shows an example of a cross section a-a′ in FIG. 4A.

FIG. 4C shows an example of a cross section b-b′ in FIG. 4A.

FIG. 5 shows an example of a doping concentration distribution on a cross section c-c′ in FIG. 1C.

FIG. 6 shows an example of relationship between a peak doping concentration of a carrier stop region and reverse recovery loss Err.

FIG. 7 shows an example of relationship between a peak doping concentration of a carrier stop region and forward direction voltage Vf of a diode portion.

FIG. 8 shows an example of relationship between reverse recovery loss Err and forward direction voltage Vf of a diode portion.

### DESCRIPTION OF EXEMPLARY EMBODIMENTS

Hereinafter, the present invention will be described through embodiments of the invention, but the following embodiments do not limit the invention according to the claims. In addition, not all combinations of features described in the embodiments are essential to the solution of the invention.

In the present specification, one side in a direction parallel to a depth direction of a semiconductor substrate is referred to as an “upper” side, and the other side is referred to as a “lower” side. One surface of two principal surfaces of a substrate, a layer, or another member is referred to as a front surface, and the other surface is referred to as a back surface. “Upper”, “lower”, “front”, and “back” directions are not limited to a direction of gravity, or a direction of an attachment to the substrate or the like when a semiconductor device is mounted.

In the present specification, technical matters may be described with orthogonal coordinate axes consisting of an X axis, a Y axis, and a Z axis. In the present specification, a plane parallel to a front surface of the semiconductor substrate is referred to as an XY plane, and a depth direction of the semiconductor substrate is referred to as the Z axis. It should be noted that, in the present specification, a case where the semiconductor substrate is viewed in a Z axis direction is referred to as a top view.

Each example embodiment shows an example in which a first conductivity type is an N type and a second conductivity type is a P type, but the first conductivity type may be the P type and the second conductivity type may be the N type. In this case, conductivity types of the substrate, the layer, a region, and the like in each example embodiment respectively have opposite polarities.

In the present specification, in a layer or a region specified with N or P, electrons or holes are meant to be majority carriers, respectively. In addition, a layer or region denoted by the symbol “+” or “−” attached to the character N or P represents that the layer or region has a higher doping concentration or a lower doping concentration respectively, than a layer or region without this symbol. Further, the symbol “++” represents that a doping concentration is higher than “+”, and the symbol “−−” represents that a doping concentration is lower than “−”.

In the present specification, a doping concentration refers to a concentration of a donor or an acceptorized dopant. Therefore, the unit is /cm³. In the present specification, a difference of concentrations of a donor and an acceptor (that is, a net doping concentration) may be set to be the doping concentration. In this case, the doping concentration can be measured by an SRP method. In addition, a chemical concentration of the donor and the acceptor may also be set to be a doping concentration. In this case, the doping concentration can be measured by an SIMS method. Unless otherwise limited, any one of the above may be used as a doping concentration. Unless otherwise limited, a peak value of a doping concentration distribution in a doping region may be set to be a doping concentration in the doping region.

In addition, in the present specification, a dosage refers to the number of ions implanted in a wafer per unit area when ions are implanted. Therefore, the unit is /cm². It should be noted that a dosage of a semiconductor region can be taken as an integral concentration which is obtained by integrating doping concentrations across the semiconductor region in the depth direction. The unit of the integral concentration is /cm². Therefore, the dosage may be treated as the same as the integral concentration. The integral concentration may also be set to be an integral value within a half-value width. In the case of being overlapped by spectrum of another semiconductor region, the integral concentration may be derived without the influence of another semiconductor region.

Therefore, in the present specification, the level of the doping concentration can be read as the level of the dosage. That is, if the doping concentration of one region is higher than the doping concentration of another region, it can be understood that the dosage of the one region is higher than the dosage of the another region.

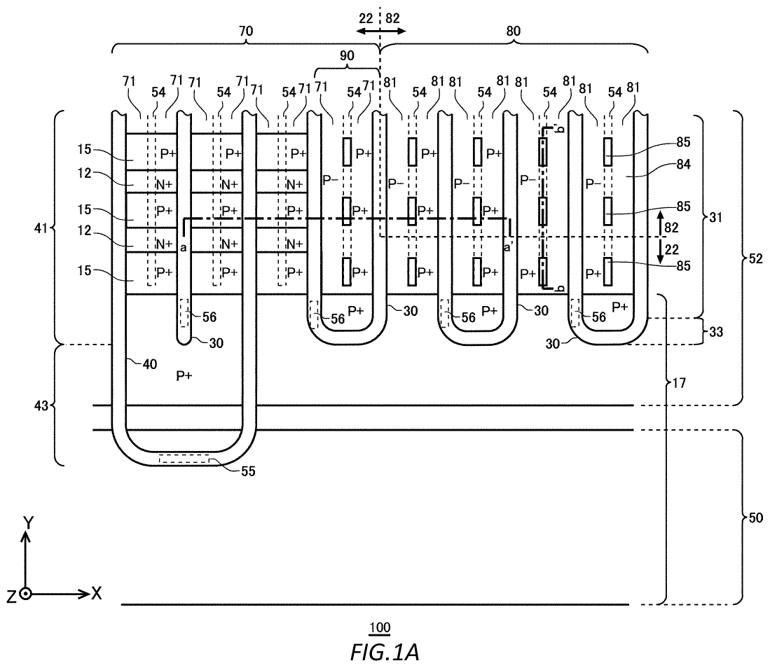

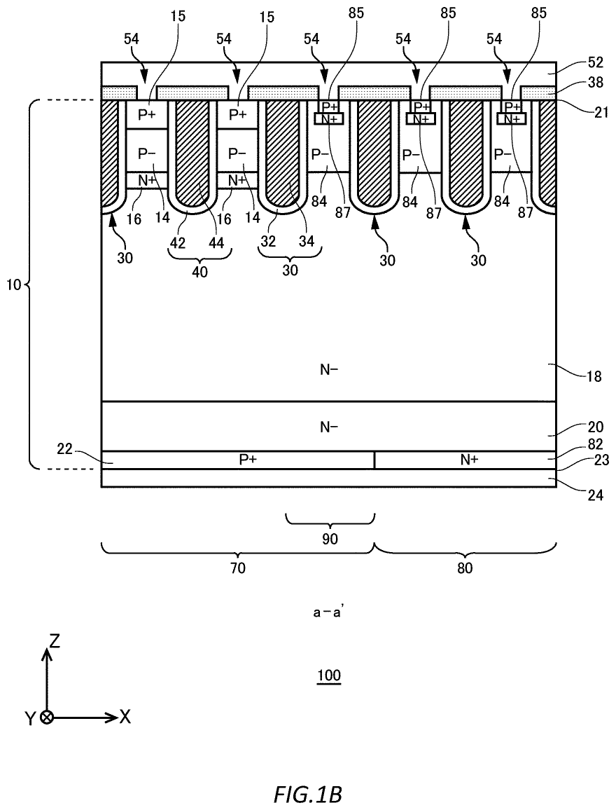

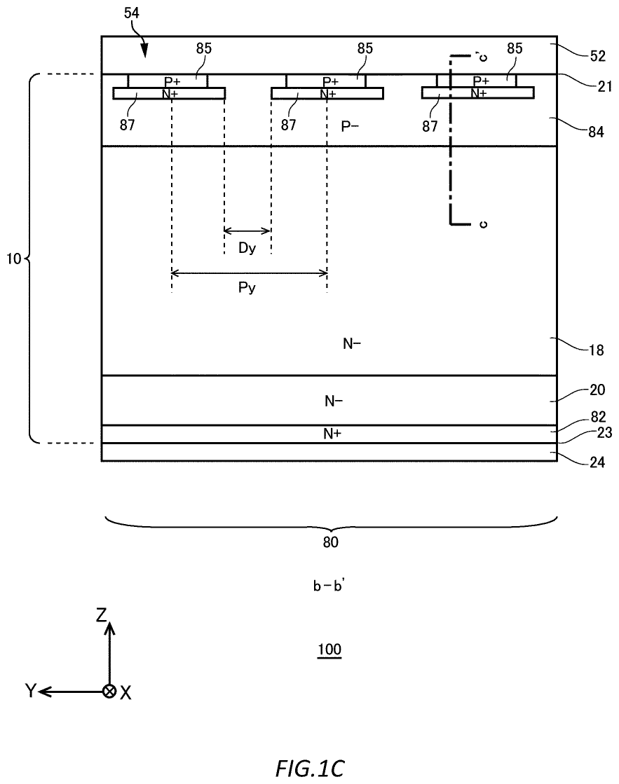

FIG. 1A shows an example of a top view of a semiconductor device 100 according to Example Embodiment 1. The semiconductor device 100 includes a semiconductor substrate having a transistor portion 70 including a transistor element such as an IGBT and a diode portion 80 including a diode element such as a free wheel diode (FWD). For example, the semiconductor device 100 is a reverse conducting IGBT (RC-IGBT).

It should be noted that, in the present specification, when simply referred to as the top view, it means viewing from a front surface side of the semiconductor substrate. In the present example, an array direction of the transistor portion 70 and the diode portion 80 in the top view is referred to as an X axis, a direction perpendicular to the X axis on a front surface of the semiconductor substrate is referred to as a Y axis, and a direction perpendicular to the front surface of the semiconductor substrate is referred to as a Z axis.

Each of the transistor portion 70 and the diode portion 80 may have a longitudinal length in an extending direction. That is, length of the transistor portion 70 in a Y axis direction is larger than its width in an X axis direction. Similarly, length of the diode portion 80 in the Y axis direction is larger than its width in the X axis direction. The extending direction of the transistor portion 70 and the diode portion 80, and a longitudinal direction of each trench portion described later may be the same.

The transistor portion 70 is a region where a collector region 22 provided on a back surface side of the semiconductor substrate is projected onto the front surface of the semiconductor substrate. The collector region 22 in the present example is of a P+ type as an example. The transistor portion 70 includes a transistor such as the IGBT.

In the transistor portion 70, an emitter region 12 of an N type, a base region 14 of a P type, and a gate trench portion 40 having a gate conductive portion and a gate dielectric film are arranged at regular intervals on the front surface side of the semiconductor substrate.

The diode portion 80 is a region where a cathode region 82 provided on the back surface side of the semiconductor substrate is projected onto the front surface of the semiconductor substrate. The cathode region 82 in the present example is of an N+ type as an example. The diode portion 80 includes a diode such as a free wheel diode (FWD) provided in direct contact with the transistor portion 70 on the front surface of the semiconductor substrate. The back surface of the semiconductor substrate may be provided with a collector region of the P+ type in a region other than the cathode region.

The semiconductor substrate may be a silicon substrate, may be a silicon carbide substrate, or may be a nitride semiconductor substrate such as gallium nitride, or the like. The semiconductor substrate in the present example is a silicon substrate.

The semiconductor device 100 in the present example includes the gate trench portion 40, a dummy trench portion 30, the emitter region 12, the base region 14, a first contact region 15, a well region 17, an anode region 84, and a second contact region 85 which are provided on the front surface side of the semiconductor substrate. The gate trench portion 40 and the dummy trench portion 30 are each an example of the trench portion.

In addition, the semiconductor device 100 in the present example includes a gate metal layer 50 and an emitter electrode 52 which are provided above the front surface of the semiconductor substrate. An interlayer dielectric film is provided between the emitter electrode 52 and the gate metal layer 50, and the front surface of the semiconductor substrate, but it is omitted in FIG. 1A. In the interlayer dielectric film in the present example, contact holes 54, 55, and 56 are provided penetrating the interlayer dielectric film. In FIG. 1A, each of the contact holes is indicated by a broken line.

The emitter electrode 52 is provided above the gate trench portion 40, the dummy trench portion 30, the emitter region 12, the base region 14, the first contact region 15, the well region 17, the anode region 84, and the second contact region 85. The emitter electrode 52 passes through the contact hole 54, and is electrically connected to the emitter region 12, the base region 14, the first contact region 15, the anode region 84, and the second contact region 85 in the front surface of the semiconductor substrate.

The emitter electrode 52 and the gate metal layer 50 are formed of a material including metal. At least part of a region of the emitter electrode 52 may be formed of aluminum, or alloy mainly composed of aluminum (for example, aluminum-silicon alloy, aluminum-silicon-copper alloy, or the like). At least part of a region of the gate metal layer 50 may be formed of aluminum, or alloy mainly composed of aluminum (for example, aluminum-silicon alloy, aluminum-silicon-copper alloy, or the like).

The emitter electrode 52 and the gate metal layer 50 may have a barrier metal formed of titanium, a titanium compound, or the like under the region formed of aluminum or the like. The emitter electrode 52 and the gate metal layer 50 are provided separately from each other.

The contact hole 55 connects the gate conductive portion in the gate trench portion 40 of the transistor portion 70 to the gate metal layer 50. In the contact hole 55, a plug formed of tungsten or the like may be provided through the barrier metal.

The contact hole 56 connects a dummy conductive portion in the dummy trench portion 30 provided in the transistor portion 70 and the diode portion 80 to the emitter electrode 52. In the contact hole 56, the plug formed of tungsten or the like may be provided through the barrier metal.

The gate trench portions 40 are arrayed at predetermined intervals along a predetermined array direction (the X axis direction in the present example). The gate trench portion 40 in the present example may have: two extending portions 41 that extend along an extending direction (the Y axis direction in the present example) which is parallel to the front surface of the semiconductor substrate and which is perpendicular to the array direction; and a connecting portion 43 that connects the two extending portions 41.

At least part of the connecting portion 43 is preferably formed in a curved shape. Connecting ends of the two extending portions 41 of the gate trench portions 40 can reduce electric field strength at the ends of the extending portions 41. At the connecting portion 43 of the gate trench portion 40, the gate metal layer 50 may be connected to the gate conductive portion.

The dummy trench portion 30 is a trench portion in which the dummy conductive portion provided therein is electrically connected to the emitter electrode 52. The dummy trench portions 30 are arrayed, similarly to the gate trench portion 40, at predetermined intervals along a predetermined array direction (the X axis direction in the present example). The dummy trench portion 30 in the present example may have, similarly to the gate trench portion 40, a U shape on the front surface of the semiconductor substrate. That is, the dummy trench portion 30 may have two extending portions 31 which extend along the extending direction and a connecting portion 33 which connects the two extending portions 31.

The transistor portion 70 in the present example has a structure in which one gate trench portion 40 and two dummy trench portions 30 are repetitively arrayed. That is, the transistor portion 70 in the present example has the gate trench portions 40 and the dummy trench portions 30 at a ratio of 1:1. For example, in the transistor portion 70, the extending portions 31 and the extending portions 41 are alternately arrayed in the array direction.

It should be noted that the ratio of the gate trench portions 40 and the dummy trench portions 30 is not limited to that in the present example. The ratio of the gate trench portions 40 and the dummy trench portions 30 may be 1:2, or may be 2:3. Alternatively, the transistor portion 70 in the present example may have a so-called full-gate structure in which the dummy trench portion 30 is not provided but only the gate trench portions 40 are provided in the transistor portion 70.

The well region 17 is provided closer to the front surface of the semiconductor substrate than the drift region 18 which will be described later. The well region 17 is an example of a well region provided on an edge side of the semiconductor device 100. The well region 17 is of a P++ type as an example. The well region 17 is provided within a predetermined range from an end of an active region on a side where the gate metal layer 50 is provided.

A diffusion depth of the well region 17 may be larger than depths of the gate trench portion 40 and the dummy trench portion 30. Parts of regions of the gate trench portion 40 and the dummy trench portion 30 on a gate metal layer 50 side are provided in the well region 17. Bottoms of ends of the gate trench portion 40 and the dummy trench portion 30 in the extending direction may be covered with the well region 17.

The contact hole 54 is provided above each of the emitter region 12 and the first contact region 15 in the transistor portion 70. The contact hole 54 is also provided above the anode region 84 and the second contact region 85 in the diode portion 80. No contact holes 54 are provided above the well regions 17 provided at both ends in the Y axis direction. Thus, the interlayer dielectric film is provided with one or a plurality of contact holes 54. The contact hole 54 in the present example may be provided extending in the extending direction.

A mesa portion 71 and a mesa portion 81 are provided in direct contact with the trench portion in a plane parallel to the front surface of the semiconductor substrate. The mesa portion may be a portion of the semiconductor substrate sandwiched between two trench portions adjacent to each other, and may be a portion ranging from the front surface of the semiconductor substrate to a depth of the lowermost bottom portion of each trench portion. An extending portion of each trench portion may be regarded as one trench portion. That is, a region sandwiched between two extending portions may be defined as a mesa portion.

The mesa portion 71 is provided in direct contact with at least one of the dummy trench portion 30 or the gate trench portion 40 in the transistor portion 70. The mesa portion 71 has the well region 17, the emitter region 12, the base region 14, and the first contact region 15 in the front surface of the semiconductor substrate. The mesa portion 81 is provided in direct contact with the dummy trench portion 30 in the diode portion 80. The mesa portion 81 has the well region 17, the anode region 84, and the second contact region 85 in the front surface of the semiconductor substrate.

The base region 14 is a region in the transistor portion 70, which is provided on the front surface side of the semiconductor substrate. The anode region 84 is a region in the diode portion 80, which is provided on the front surface side of the semiconductor substrate. The base region 14 and the anode region 84 in the present example are of a P− type as an example. A doping concentration of the anode region 84 in the present example is lower than a doping concentration of the base region 14. In the present example, lowering the doping concentration of the anode region 84 can suppress hole implantation during reverse recovery.

The emitter region 12 is of the same conductivity type as that of the drift region 18 and has a higher doping concentration than the drift region 18. The emitter region 12 in the present example is of the N+ type as an example. An example of a dopant of the emitter region 12 includes arsenic (As). The emitter region 12 is provided in contact with the gate trench portion 40 at a front surface of the mesa portion 71. The emitter region 12 may be provided extending in the X axis direction from one of two trench portions sandwiching the mesa portion 71 to the other of the two trench portions.

In addition, the emitter region 12 may be or may not be in contact with the dummy trench portion 30. The emitter region 12 in the present example is in contact with the dummy trench portion 30. The emitter region 12 is not provided in the mesa portion 81.

The first contact region 15 is of the same conductivity type as that of the base region 14, and has a higher doping concentration than the base region 14. The first contact region 15 in the present example is of the P+ type as an example. The first contact region 15 in the present example is provided at the front surface of the mesa portion 71. The first contact region 15 is provided extending in the X axis direction from one of two trench portions sandwiching the mesa portion 71 to the other of the two trench portions.

The second contact region 85 is of the same conductivity type as that of the anode region 84, and has a higher doping concentration than the anode region 84. The second contact region 85 in the present example is of the P+ type as an example. The second contact region 85 in the present example is provided at a front surface of the mesa portion 81. Providing the second contact region 85 in the mesa portion 81 can compensate for the low doping concentration of the anode region 84 and enable ohmic junction.

The second contact region 85 may be formed in the same process as the first contact region 15. In FIG. 1A, the second contact regions 85 are arrayed at positions corresponding to positions of the first contact regions 15 in the X axis direction, but the present invention is not limited thereto. If the second contact regions 85 are formed in a different process from the first contact region 15, the second contact regions 85 may be arrayed at positions independent of the positions of the first contact regions 15.

The second contact regions 85 in the present example are discretely provided in the Y axis direction. In addition, the second contact region 85 is provided apart from a side wall of the dummy trench portion 30 in the X axis direction. The anode region 84 is exposed in a region where the second contact regions 85 are not provided, at the front surface of the mesa portion 81. That is, the second contact region 85 in the present example is enclosed by the anode region 84 in the top view.

In the present example, the emitter regions 12 and the first contact regions 15 are alternately provided in the Y axis direction, at the front surface of the mesa portion 71. On the other hands, the second contact regions 85 with a high doping concentration are discretely provided and the anode region 84 with a low doping concentration is provided, at the front surface of the mesa portion 81. Thus, reducing a total amount of holes in the mesa portion 81 can suppress the hole implantation during reverse recovery.

The transistor portion 70 in the present example has a boundary region 90 in direct contact with the diode portion 80. The boundary region 90 is part of the transistor portion 70, but has a different front surface structure from another region of the transistor portion 70. In the present specification, a different configuration from the another region of the transistor portion 70 among configurations of the boundary region 90 will be mainly described, and description of a common configuration will be omitted.

At the front surface of the mesa portion 71 of the boundary region 90 in the present example, the second contact regions 85 are discretely provided, and the anode region 84 is provided in the region where the second contact regions 85 are not provided. In addition, the emitter region 12 and the first contact region 15 are not provided in the mesa portion 71 of the boundary region 90. That is, the boundary region 90 in the present example has a front surface structure similar to that of the diode portion 80, which can suppress the hole implantation during reverse recovery.

FIG. 1B shows an example of a cross section a-a′ in FIG. 1A. FIG. 1C shows an example of a cross section b-b′ in FIG. 1A. The cross section a-a′ is an XZ plane passing through the first contact region 15 and the second contact region 85. The cross section b-b′ is a YZ plane along the contact hole 54 of the mesa portion 81.

The semiconductor device 100 in the present example has a semiconductor substrate 10, an interlayer dielectric film 38, the emitter electrode 52, and a collector electrode 24. The emitter electrode 52 is provided above the semiconductor substrate 10 and the interlayer dielectric film 38.

The drift region 18 is provided in the semiconductor substrate 10. The drift region 18 in the present example is of the N− type as an example. The drift region 18 may be a region that has remained without other doping regions being formed in the semiconductor substrate 10. That is, a doping concentration of the drift region 18 may be a doping concentration of the semiconductor substrate 10.

A buffer region 20 is provided below the drift region 18. The buffer region 20 in the present example is of the same conductivity type as that of the drift region 18, and is of N type as an example. A doping concentration of the buffer region 20 is higher than the doping concentration of the drift region 18. The buffer region 20 may serve as a field stop layer which prevents a depletion layer expanding from a lower surface side of the base region 14 from reaching the collector region 22 and the cathode region 82.

The collector region 22 is provided below the buffer region 20 in the transistor portion 70, and is of a different conductivity type from that of the drift region 18. The cathode region 82 is provided below the buffer region 20 in the diode portion 80, and is of the same conductivity type as that of the drift region 18. A boundary between the collector region 22 and the cathode region 82 is a boundary between the transistor portion 70 and the diode portion 80.

The collector electrode 24 is provided on a back surface 23 of the semiconductor substrate 10, and is in contact with both the collector region 22 and the cathode region 82. The collector electrode 24 is formed of a conductive material such as metal, or by stacking conductive materials.

The base region 14 is provided above the drift region 18 in the mesa portion 71 of a region other than the boundary region 90, and is of a different conductivity type from that of the drift region 18. The base region 14 in the present example is of the P− type as an example. The base region 14 is provided in contact with the gate trench portion 40. The base region 14 may be provided in contact with the dummy trench portion 30.

The anode region 84 is provided above the drift region 18 in the mesa portion 71 of the boundary region 90 and the mesa portion 81 of the diode portion 80, and is of a different conductivity type from that of the drift region 18. The anode region 84 in the present example is of the P− type as an example. The doping concentration of the anode region 84 is lower than the doping concentration of the base region 14. The anode region 84 is provided in contact with the dummy trench portion 30.

The emitter region 12 is provided between the base region 14 and the front surface 21 of the semiconductor substrate 10. The emitter region 12 in the present example is provided in the mesa portion 71 of the region other than the boundary region 90, and is not provided in the mesa portion 71 of the boundary region 90 and in the mesa portion 81. The emitter region 12 is provided in contact with the gate trench portion 40. The emitter region 12 may be or may not be in contact with the dummy trench portion 30.

When the diode portion 80 is brought into conduction, electronic current flows from the cathode region 82 to the anode region 84. When the electronic current reaches the anode region 84, conductivity modulation occurs and hole current flows from the anode region 84. In addition, the electronic current diffused from the cathode region 82 facilitates the hole implantation from the first contact region 15 of the transistor portion 70 as well, which increases hole density of the semiconductor substrate 10. As a result, increased time required for the hole to disappear when the diode portion 80 is turned off increases reverse recovery peak current and increases reverse recovery loss.

A technique for suppressing such hole current is known, in which a lifetime control region including a lifetime killer is provided on the front surface side of the semiconductor substrate. As an example, the lifetime killer is an electron beam implanted into the entire semiconductor substrate or helium, an electron beam, a proton, or the like implanted to a predetermined depth. The lifetime control region is a crystal defect formed in the semiconductor substrate by implanting the lifetime killer. The lifetime control region facilitates recombination disappearance of an electron and a hole generated when a diode portion is brought into conduction, and reduces the reverse recovery loss.

In the present example, the lifetime control region including the lifetime killer is not provided on a front surface 21 side of the semiconductor substrate 10. In the present example, it is possible to suppress the hole implantation during reverse recovery even if the lifetime control region is not provided, by discretely providing the second contact regions 85 with a high doping concentration in the mesa portion 71 of the boundary region 90 and in the mesa portion 81 and by setting the doping concentration of the anode region 84 lower than the doping concentration of the base region 14.

The contact hole 54 is provided penetrating the interlayer dielectric film 38 in a Z axis direction, and electrically connects the emitter electrode 52 and the semiconductor substrate 10. The barrier metal formed of titanium, a titanium compound, or the like may be provided in the contact hole 54. The plug formed of tungsten or the like may be further provided through the barrier metal, in the contact hole 54. In addition, the contact hole 54 may have a trench contact structure in which a concave portion is provided in the front surface 21 of the semiconductor substrate 10.

The second contact region 85 is provided below the contact hole 54. For example, the second contact region 85 is formed by ion-implanting a dopant such as boron (B) from a lower end of the contact hole 54. In the X axis direction, width of the second contact region 85 may be equal to or larger than width of the lower end of the contact hole 54. A doping concentration of the second contact region 85 in the present example is 1E18 cm⁻³ or more and 1E20 cm⁻³ or less. It should be noted that E means a power of 10, and for example, 1E16 cm⁻³ means 1×10¹⁶ cm⁻³.

The second contact region 85 in the present example is provided apart from a side wall of the trench portion in the X axis direction. In the Y axis direction, a pitch between the second contact regions 85, that is, distance from a center of the second contact region 85 in the Y axis direction to a center of the adjacent second contact region 85 in the Y axis direction is 0.4 μm or more. In the Z axis direction, thickness of the second contact region 85, that is, distance from the front surface 21 of the semiconductor substrate 10 to a lower end of the second contact region 85 is 0.1 μm or more and 0.3 μm or less.

A carrier stop region 87 is provided below the second contact region 85. The carrier stop region 87 is of the same conductivity type as that of the drift region 18, and has a higher doping concentration than the drift region 18. The carrier stop region 87 in the present example is of the N+ type as an example.

For example, the carrier stop region 87 is formed by ion-implanting the dopant such as arsenic (As) from the lower end of the contact hole 54. A doping concentration of the carrier stop region 87 is 1E16 cm⁻³ or more and 1E18 cm⁻³ or less. Providing the carrier stop region 87 can suppress the hole implantation from the second contact region 85 during reverse recovery.

The carrier stop regions 87 in the present example are discretely provided in the Y axis direction. Thus, the anode region 84 below the carrier stop region 87 in the present example is also electrically connected to the second contact region 85. Providing an interval between the adjacent carrier stop regions 87 suppresses excessive increase in the forward direction voltage Vf of the diode portion 80 and facilitates a current flow. As shown in FIG. 1C, in the Y axis direction, distance Dy between the adjacent carrier stop regions 87 is 0.4 μm or more. Maintaining the distance Dy further diffuse the dopant ion-implanted from the lower end of the contact hole 54, connects the adjacent carrier stop regions 87, and prevents interruption of a current path.

As shown in FIG. 1C, in the Y axis direction, a pitch Py between the carrier stop regions 87, that is, distance from a center of the carrier stop region 87 in the Y axis direction to a center of the adjacent carrier stop region 87 in the Y axis direction is 0.4 μm or more and equal to or smaller than the pitch between the second contact regions 85. In the present example, the carrier stop regions 87 and the second contact regions 85 are arrayed at regular intervals with the same pitch in the Y axis direction.

As shown in FIG. 1B, the carrier stop region 87 in the present example is provided apart from the side wall of the dummy trench portion 30 in the X axis direction. In the present example, in the X axis direction, width of the carrier stop region 87 is larger than the width of the second contact region 85. In the X axis direction, the width of the carrier stop region 87 is larger than width of the contact hole 54. In addition, in the Y axis direction, the width of the carrier stop region 87 is larger than the width of the second contact region 85. This can more reliably suppress the hole implantation from the second contact region 85 during reverse recovery.

An upper end of the carrier stop region 87 may be within a range of 0.1 μm or more and 0.3 μm or less from the front surface 21 of the semiconductor substrate 10 in the X axis direction. The upper end of the carrier stop region 87 in the present example is in contact with the lower end of the second contact region 85. This suppresses the hole from the second contact region 85 from passing through between the second contact region 85 and the carrier stop region 87 and being implanted into the semiconductor substrate 10 during reverse recovery. A lower end of the carrier stop region 87 may be closer to the front surface 21 of the semiconductor substrate 10 than a lower end of the anode region 84. That is, the lower end of the carrier stop region 87 may be covered with the anode region 84.

The accumulation region 16 is provided below the base region 14. The accumulation region 16 in the present example is of the same conductivity type as that of the drift region 18, and is of the N+ type as an example. The drift region 18 may be provided with two or more layers of the accumulation region 16. The accumulation region 16 may not be provided below the anode region 84, that is, in the boundary region 90 and the diode portion 80.

In addition, the accumulation region 16 is provided in contact with the gate trench portion 40. The accumulation region 16 may be or may not be in contact with the dummy trench portion 30. A doping concentration of the accumulation region 16 is higher than the doping concentration of the drift region 18. Providing the accumulation region 16 can increase carrier implantation enhancement effect (IE effect), and reduce ON voltage of the transistor portion 70.

One or more gate trench portions 40 and one or more dummy trench portions 30 are provided in the front surface 21 of the semiconductor substrate 10. Each trench portion is provided extending in a depth direction (the Z axis direction) from the front surface 21 of the semiconductor substrate 10 to the drift region 18. In a region provided with at least any one of the emitter region 12, the base region 14, the first contact region 15, the accumulation region 16, or the anode region 84, each trench portion also penetrates the region described above to reach the drift region 18. A configuration of the trench portion penetrating the doping region is not limited to what is manufactured in the order of forming a doping region and then forming trench portions. The configuration of the trench portion penetrating the doping region also includes what is manufactured in the order of forming trench portions and then forming a doping region between the trench portions.

The gate trench portion 40 has a gate trench, a gate dielectric film 42, and the gate conductive portion 44 which are provided in the front surface 21 of the semiconductor substrate 10. The gate dielectric film 42 is provided covering an inner wall of the gate trench. The gate dielectric film 42 may be formed by oxidizing or nitriding a semiconductor on the inner wall of the gate trench. The gate conductive portion 44 is provided farther inward in the gate trench than the gate dielectric film 42. The gate dielectric film 42 insulates the gate conductive portion 44 from the semiconductor substrate 10. The gate conductive portion 44 is formed of a conductive material such as polysilicon. The gate trench portion 40 is covered by the interlayer dielectric film 38 on the front surface 21 of the semiconductor substrate 10.

The gate conductive portion 44 includes a region facing the base region 14 that is adjacent to the gate conductive portion 44 on the mesa portion 71 side with the gate dielectric film 42 interposed therebetween, in the depth direction of the semiconductor substrate 10. When predetermined voltage is applied to the gate conductive portion 44, a channel due to an electron inversion layer is formed in a surface layer of a boundary surface which is of the base region 14 and which is in contact with the gate trench.

The dummy trench portion 30 may have the same structure as the gate trench portion 40. The dummy trench portion 30 has a dummy trench, a dummy dielectric film 32, and a dummy conductive portion 34 which are provided on the front surface 21 side of the semiconductor substrate 10. The dummy dielectric film 32 is provided covering an inner wall of the dummy trench. The dummy conductive portion 34 is provided in the dummy trench, and is provided farther inward than the dummy dielectric film 32. The dummy dielectric film 32 insulates the dummy conductive portion 34 from the semiconductor substrate 10. The dummy trench portion 30 is covered by the interlayer dielectric film 38 on the front surface 21 of the semiconductor substrate 10.

The interlayer dielectric film 38 is provided on the front surface 21 of the semiconductor substrate 10. The emitter electrode 52 is provided above the interlayer dielectric film 38. The interlayer dielectric film 38 is provided with the one or the plurality of contact holes 54 for electrically connecting the emitter electrode 52 and the semiconductor substrate 10. Similarly, the contact hole 55 and the contact hole 56 may be provided penetrating the interlayer dielectric film 38.

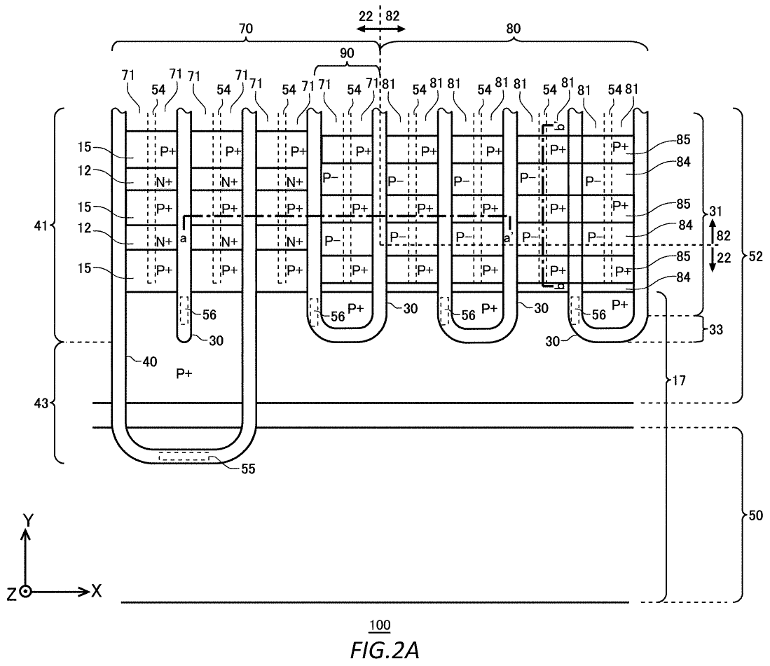

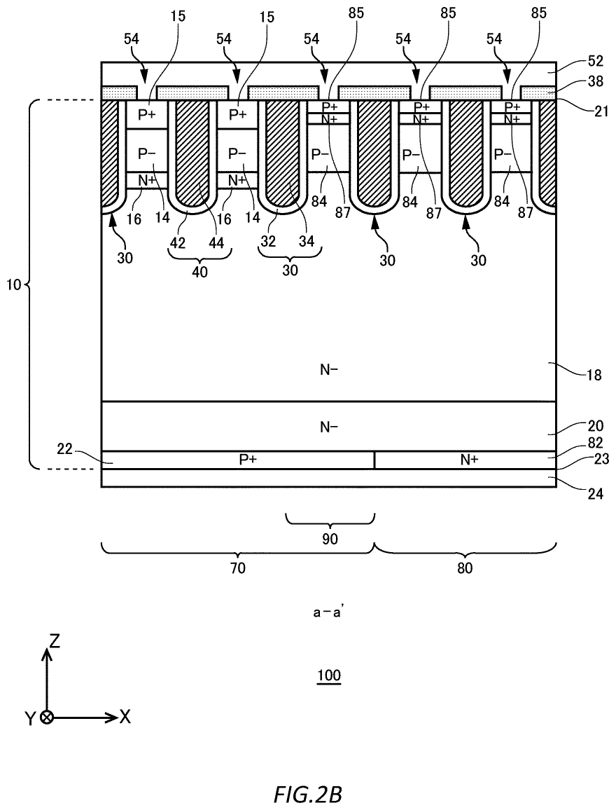

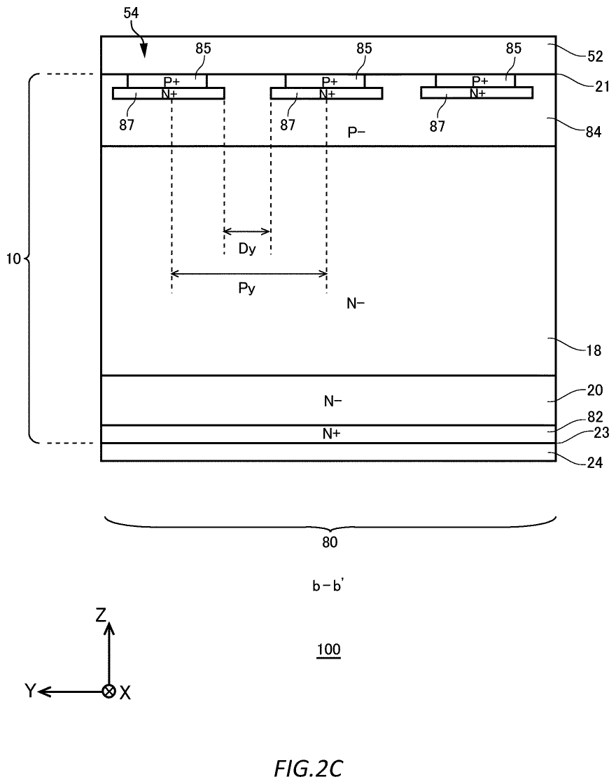

FIG. 2A shows an example of a top view of a semiconductor device 100 according to Example Embodiment 2. FIG. 2B shows an example of a cross section a-a′ in FIG. 2A. FIG. 2C shows an example of a cross section b-b′ in FIG. 2A. The semiconductor device 100 in the present example is different from the semiconductor device 100 according to Example Embodiment 1 described above in a configuration of the second contact region 85. Here, difference with Example Embodiment 1 will be mainly described, and description of a common matter will be omitted.

The second contact region 85 in the present example is provided extending from a side wall of the dummy trench portion 30 to a side wall of the adjacent dummy trench portion 30 in an X axis direction. That is, in the top view, the second contact regions 85 and the anode regions 84 are alternately provided in a Y axis direction in the mesa portion 81. In the top view, in the mesa portion 81, an area ratio of the second contact region 85 to the anode region 84 in the present example is greater than that in Example Embodiment 1.

In the present example, the carrier stop region 87 is also provided extending from the side wall of the dummy trench portion 30 to the side wall of the adjacent dummy trench portion 30 in the X axis direction. It should be noted that an array of the carrier stop regions 87 in the Y axis direction is similar to that in Example Embodiment 1. As shown in FIG. 2C, the carrier stop regions 87 are arrayed at regular intervals with the pitch Py, and the distance Dy is maintained between the adjacent carrier stop regions 87. Thus, the anode region 84 below the carrier stop region 87 in the present example is also electrically connected to the second contact region 85.

Thus, providing the carrier stop region 87 has an effect of suppressing hole implantation during reverse recovery, which can increase area of the second contact region 85 in the present example.

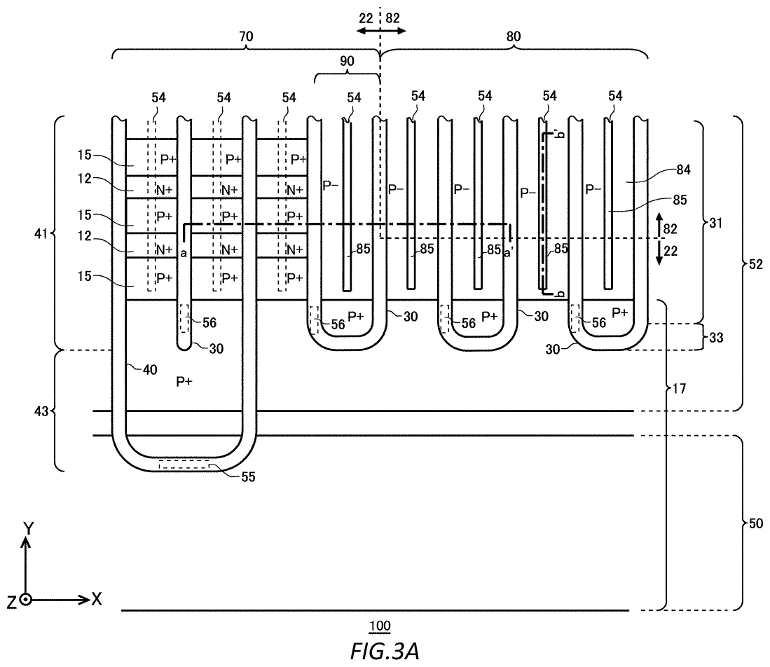

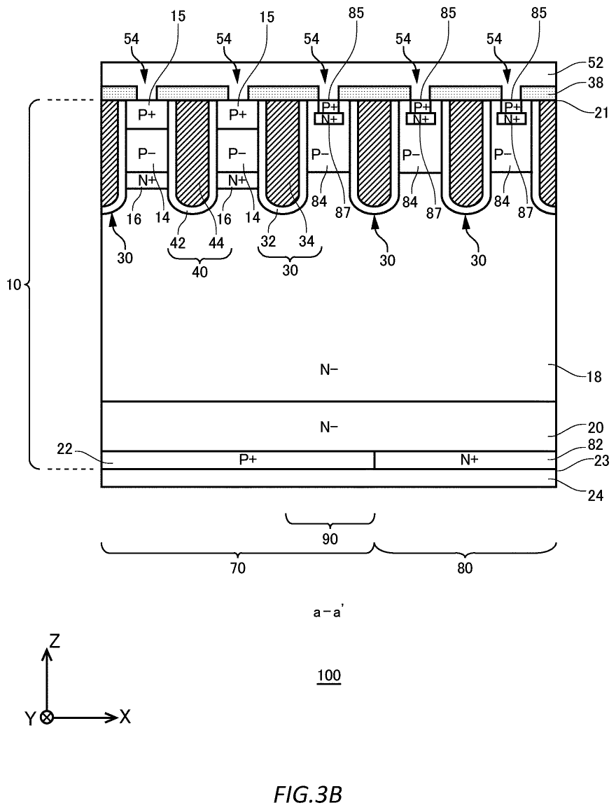

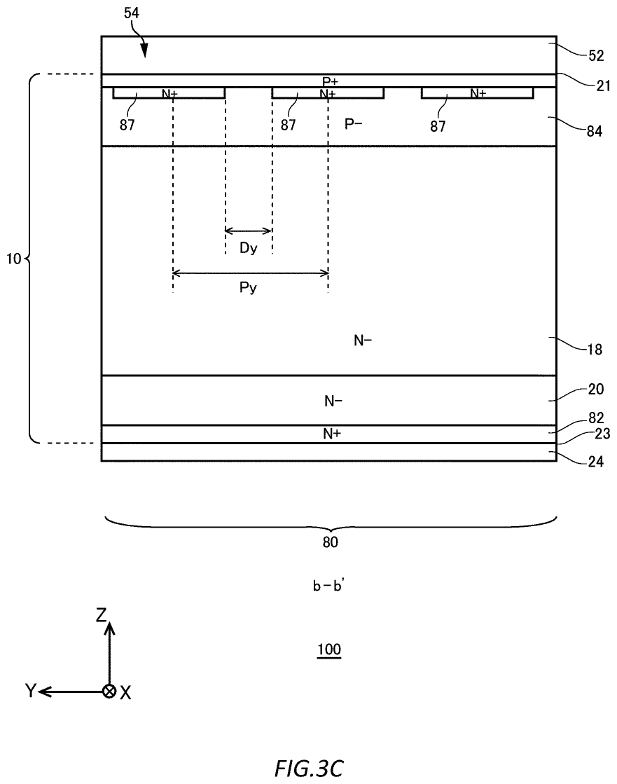

FIG. 3A shows an example of a top view of a semiconductor device 100 according to Example Embodiment 3. FIG. 3B shows an example of a cross section a-a′ in FIG. 3A. FIG. 3C shows an example of a cross section b-b′ in FIG. 3A. The semiconductor device 100 in the present example is different from the semiconductor device 100 according to Example Embodiment 1 described above in a configuration of the second contact region 85. Here, difference with Example Embodiment 1 will be mainly described, and description of a common matter will be omitted.

The second contact region 85 in the present example is provided extending in a Y axis direction. The second contact region 85 may be provided along the contact hole 54. That is, in the top view, in the mesa portion 81, the anode region 84 extends in the Y axis direction along the dummy trench portion 30, and the second contact region 85 is sandwiched between the anode regions 84 and extends in the Y axis direction. In the top view, in the mesa portion 81, an area ratio of the second contact region 85 to the anode region 84 in the present example is greater than that in Example Embodiment 1.

The carrier stop regions 87 in the present example are discretely provided below the second contact regions 85 extending in the Y axis direction. As shown in FIG. 3C, the carrier stop regions 87 are arrayed at regular intervals with the pitch Py, and the distance Dy is maintained between the adjacent carrier stop regions 87.

In an X axis direction, width of the carrier stop region 87 in the present example is larger than width of the second contact region 85. The carrier stop region 87 is provided apart from a side wall of the dummy trench portion 30 in the X axis direction.

Thus, providing the carrier stop region 87 has an effect of suppressing hole implantation during reverse recovery, which can increase area of the second contact region 85 in the present example.

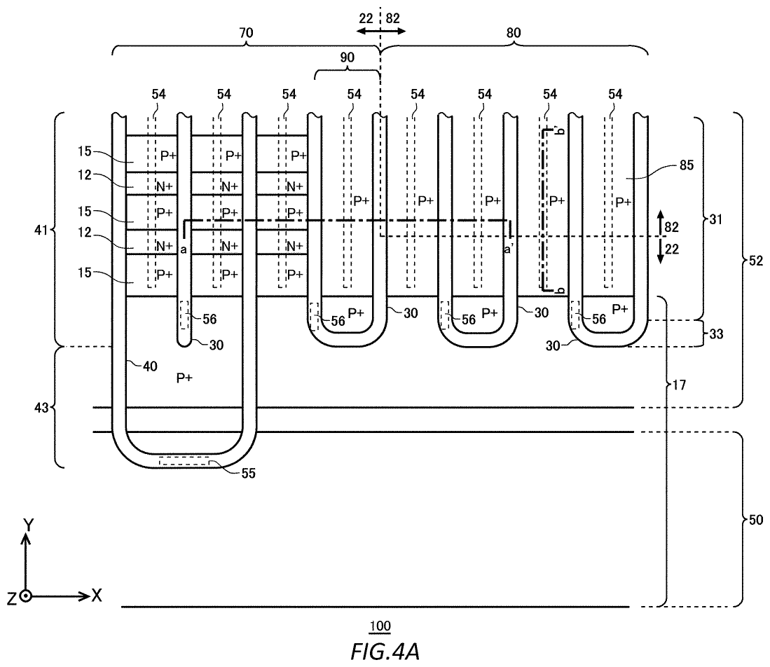

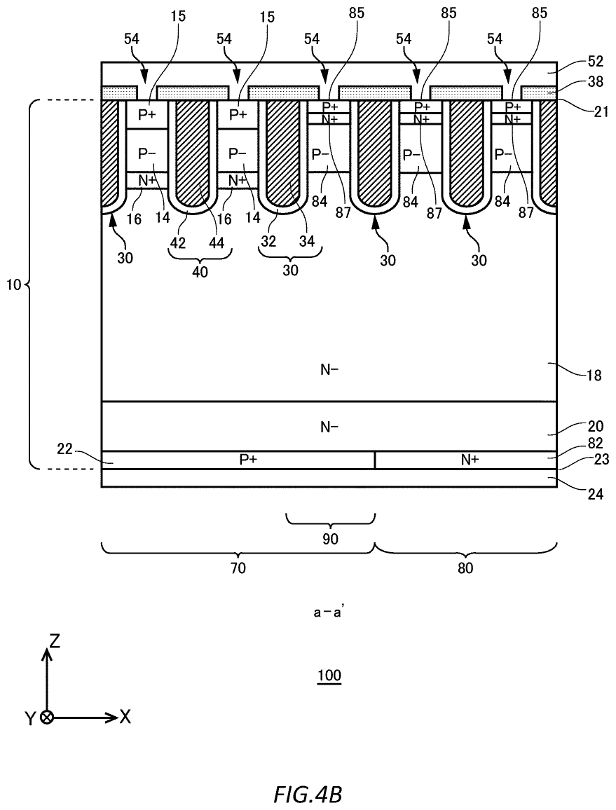

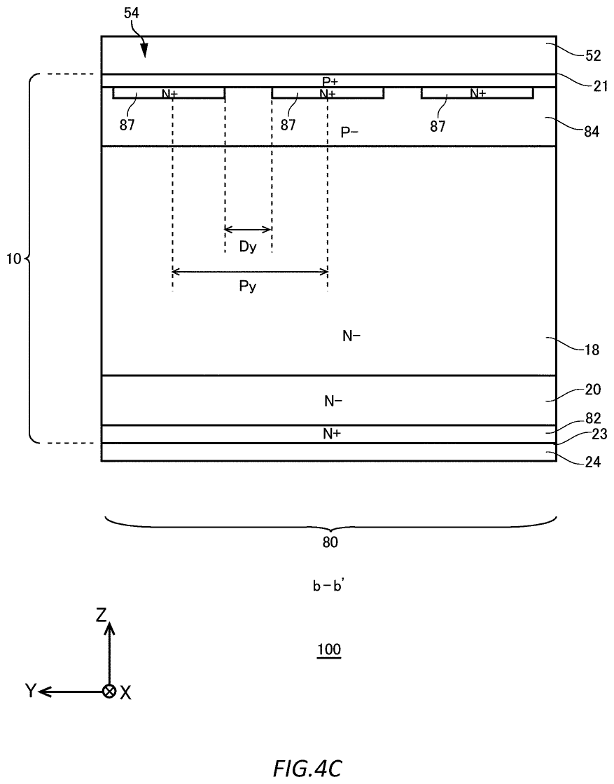

FIG. 4A shows an example of a top view of a semiconductor device 100 according to Example Embodiment 4. FIG. 4B shows an example of a cross section a-a′ in FIG. 4A. FIG. 4C shows an example of a cross section b-b′ in FIG. 4A. The semiconductor device 100 in the present example is different from the semiconductor device 100 according to Example Embodiment 1 described above in a configuration of the second contact region 85. Here, difference with Example Embodiment 1 will be mainly described, and description of a common matter will be omitted.

The second contact region 85 in the present example is provided extending from a side wall of the dummy trench portion 30 to a side wall of the adjacent dummy trench portion 30 in an X axis direction. That is, in the top view, at a front surface of the mesa portion 81, only the second contact region 85 is provided, and the anode region 84 is not exposed. In the top view, in the mesa portion 81, an area ratio of the second contact region 85 to the anode region 84 in the present example is greater than that in Example Embodiment 1.

In the present example, the carrier stop region 87 is also provided extending from the side wall of the dummy trench portion 30 to the side wall of the adjacent dummy trench portion 30 in the X axis direction. It should be noted that an array of the carrier stop regions 87 in the Y axis direction is similar to that in Example Embodiment 1. As shown in FIG. 2C, the carrier stop regions 87 are arrayed at regular intervals with the pitch Py, and the distance Dy is maintained between the adjacent carrier stop regions 87.

Thus, providing the carrier stop region 87 has an effect of suppressing hole implantation during reverse recovery, which can increase area of the second contact region 85 in the present example.

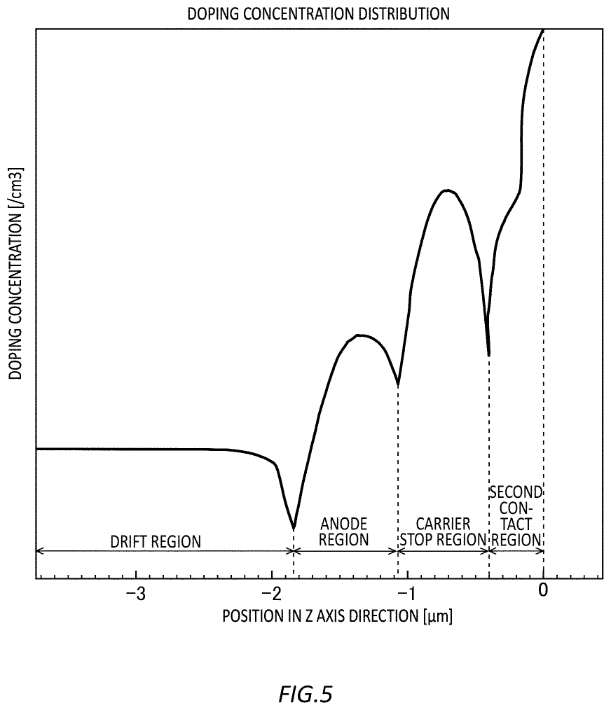

FIG. 5 shows an example of a doping concentration distribution on a cross section c-c′ in FIG. 1C. The cross section c-c′ is an XZ plane passing through the second contact region 85, the carrier stop region 87, the anode region 84, and the drift region 18 in the mesa portion 81 of the semiconductor device 100 in Example Embodiment 1. Here, a doping concentration distribution in Example Embodiment 1 will be shown as an example, but the same applies to doping concentration distributions in Example Embodiment 2, Example Embodiment 3, and Example Embodiment 4.

In FIG. 5, the horizontal axis represents a position in a Z axis direction (μm) with respect to the front surface 21 of the semiconductor substrate 10, that is, a depth from the front surface 21 of the semiconductor substrate 10, and the vertical axis represents a doping concentration (cm⁻³). The doping concentration distribution includes peak doping concentrations of the second contact region 85, the carrier stop region 87, the anode region 84, and the drift region 18 in the order from the front surface 21 of the semiconductor substrate 10 toward a −Z axis direction.

A doping concentration of the second contact region 85 in the present example is 1E18 cm⁻³ or more and 1E20 cm⁻³ or less, and a doping concentration of the carrier stop region 87 is 1E16 cm⁻³ or more and 1E18 cm⁻³ or less. In the doping concentration distribution of the carrier stop region 87 shown in FIG. 5, a valley in a +Z axis direction is a doping concentration at an upper end of the carrier stop region 87, and a valley in the −Z axis direction is a doping concentration at a lower end of the carrier stop region 87. The upper end of the carrier stop region 87 in the present example is a boundary between the carrier stop region 87 and the second contact region 85. The doping concentration at the upper end of the carrier stop region 87 is higher than a peak doping concentration of the anode region 84.

In the Z axis direction, a peak doping concentration of the carrier stop region 87 is located at distance of 0.3 μm or more and 0.7 μm or less from the front surface 21 of the semiconductor substrate 10. Distance between a position of the peak doping concentration of the carrier stop region 87 and a lower end of the second contact region 85 is 0.1 μm or more and 0.4 μm or less.

The peak doping concentration of the carrier stop region 87 in the present example is located closer to the front surface 21 of the semiconductor substrate 10 than a center of the anode region 84 in a depth direction. Here, the center of the anode region 84 in the depth direction refers to any point located at a depth equivalent to half a depth (distance in the Z axis direction) from the front surface 21 of the semiconductor substrate 10 to a lower end of the anode region 84.

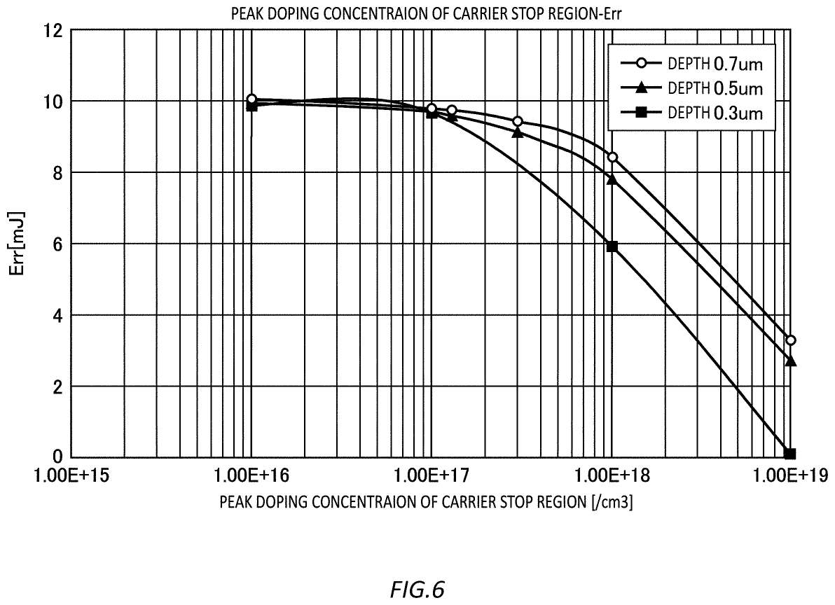

FIG. 6 shows an example of relationship between a peak doping concentration of a carrier stop region and reverse recovery loss Err. In FIG. 6, the horizontal axis represents a peak doping concentration (cm⁻³) of the carrier stop region 87, and the vertical axis represents reverse recovery loss Err (mJ). FIG. 6 shows relationship between the peak doping concentration and the reverse recovery loss Err, for the semiconductor device 100 with a varying peak doping concentration depth (distances from the front surface 21 of the semiconductor substrate 10 in a Z axis direction) of the carrier stop region 87. The semiconductor device 100 mentioned here may be any one of the semiconductor devices 100 according to Example Embodiment 1, Example Embodiment 2, and Example Embodiment 3 described above.

Graphs plotted with squares, triangles, and white circles respectively show the reverse recovery loss Err of the semiconductor device 100 in which the peak doping concentration depth of the carrier stop region 87 is 0.3 μm, 0.5 μm, and 0.7 μm. As shown in FIG. 6, effect of reducing the reverse recovery loss Err was observed when the peak doping concentration increased, and the effect was greater as a position of the peak doping concentration was deeper.

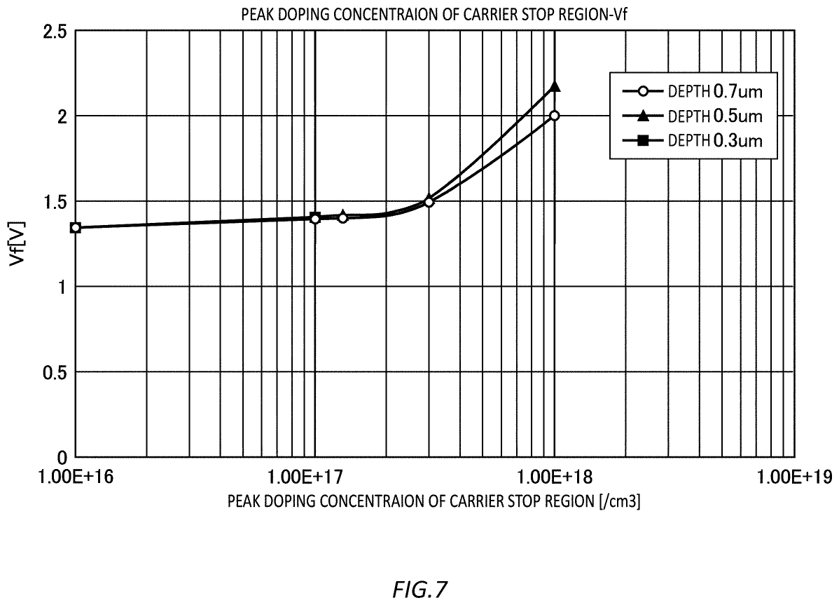

FIG. 7 shows an example of relationship between a peak doping concentration of a carrier stop region and forward direction voltage Vf of a diode portion. In FIG. 7, the horizontal axis represents a peak doping concentration (cm⁻³) of the carrier stop region 87, and the vertical axis represents forward direction voltage Vf (V) of the diode portion 80. FIG. 7 shows relationship between the peak doping concentration and the forward direction voltage Vf of the diode portion 80, for the semiconductor device 100 with a varying peak doping concentration depth of the carrier stop region 87. Setting of the peak doping concentration depth of the carrier stop region 87 is similar to that in FIG. 6.

As shown in FIG. 7, for the semiconductor device 100 in which the peak doping concentration depth of the carrier stop region 87 is 0.5 μm and 0.7 μm, the forward direction voltage Vf of the diode portion 80 increased when the peak doping concentration increased. On the other hand, for the semiconductor device 100 in which the peak doping concentration depth of the carrier stop region 87 is 0.3 μm, the forward direction voltage Vf of the diode portion 80 was not detected when the peak doping concentration increased. That is, if a position of the peak doping concentration of the carrier stop region 87 is shallow, when the peak doping concentration increases, the forward direction voltage Vf of the diode portion 80 exceeds an allowable value and current stops flowing, and the diode portion 80 stops operating as a diode.

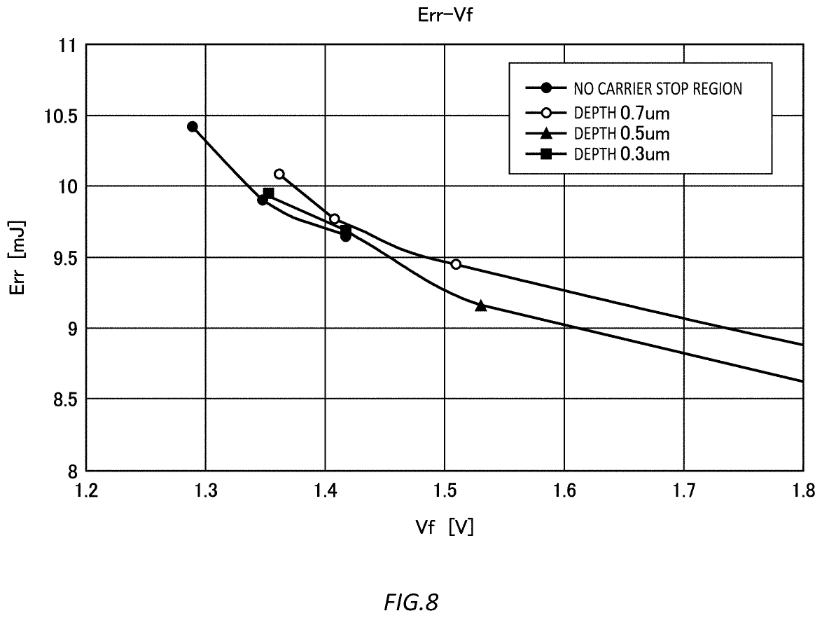

FIG. 8 shows an example of relationship between reverse recovery loss Err and forward direction voltage Vf of a diode portion. In FIG. 8, the horizontal axis represents forward direction voltage Vf (V) of the diode portion, and the vertical axis represents reverse recovery loss Err (mJ). FIG. 8 shows relationship between the reverse recovery loss Err and the forward direction voltage Vf of the diode portion, for the semiconductor device 100 with a varying peak doping concentration depth of the carrier stop region 87 and for the semiconductor device according to a comparative example in which no carrier stop region is provided. Setting of the peak doping concentration depth of the carrier stop region 87 in the semiconductor device 100 is similar to that in FIG. 6. The semiconductor device according to the comparative example has a configuration similar to that of the semiconductor device 100 except that no carrier stop region is provided.

As shown in FIG. 8, there is trade-off relationship between the reverse recovery loss Err and the forward direction voltage Vf of the diode portion. For the semiconductor device 100 in which the peak doping concentration depth of the carrier stop region 87 is 0.5 μm and 0.7 μm, the forward direction voltage Vf of the diode portion 80 increased when the reverse recovery loss Err reduced. That is, referring to both FIG. 6 and FIG. 7, when the peak doping concentration of the carrier stop region 87 increases, the forward direction voltage Vf of the diode portion 80 increases while the reverse recovery loss Err reduces, and therefore it is necessary to suppress increase in the forward direction voltage Vf within an allowable range.

On the other hand, for the semiconductor device 100 in which the peak doping concentration depth of the carrier stop region 87 is 0.3 μm, the forward direction voltage Vf of the diode portion 80 was no longer detected when the reverse recovery loss Err was reduced, and effect of reducing the reverse recovery loss Err was not observed which is equal to or greater than the effect for the semiconductor device according to the comparative example plotted with black circles.

Thus, according to the semiconductor device 100 according to the example embodiment, appropriately setting the peak doping concentration of the carrier stop region 87 and its depth within the range described above can suppress hole implantation during reverse recovery.

While the present invention has been described above using embodiments, a technical scope of the present invention is not limited to a scope described in the above-described embodiments. It is apparent to persons skilled in the art that various alterations or improvements can be made to the above-described embodiment. It is also apparent from description of the claims that the embodiments to which such alterations or improvements are made can be included in the technical scope of the present invention.

It should be noted that the operations, procedures, steps, stages, and the like of each process performed by a device, system, program, and method shown in the claims, specification, or drawings can be performed in any order as long as the order is not indicated by “prior to,” “before,” or the like and as long as the output from a previous processing is not used in a later process. Even if the process flow is described using phrases such as “first” or “next” for the sake of convenience in the claims, specification, or drawings, it does not necessarily mean that the process must be performed in this order.

### EXPLANATION OF REFERENCES

10: semiconductor substrate, 12: emitter region, 14: base region, 15: contact region, 16: accumulation region, 17: well region, 18: drift region, 20: buffer region, 21: front surface, 22: collector region, 23: back surface, 24: collector electrode, 30: dummy trench portion, 31: extending portion, 33: connecting portion, 32: dummy dielectric film, 34: dummy conductive portion, 38: interlayer dielectric film, 40: gate trench portion, 41: extending portion, 43: connecting portion, 42: gate dielectric film, 44: gate conductive portion, 50: gate metal layer, 52: emitter electrode, 54: contact hole, 55: contact hole, 56: contact hole, 70: transistor portion, 71: mesa portion, 80: diode portion, 81: mesa portion, 82: cathode region, 84: anode region, 85: second contact region, 90: boundary region, 100: semiconductor device.

What is claimed is:

1. A semiconductor device comprising a transistor portion and a diode portion, wherein
the diode portion includes:
a plurality of trench portions provided in a semiconductor substrate;
a drift region of a first conductivity type provided in the semiconductor substrate;
an anode region of a second conductivity type provided above the drift region;
a second contact region of the second conductivity type provided in a front surface of the semiconductor substrate above the anode region and having a higher doping concentration than the anode region; and
a carrier stop region of the first conductivity type provided below the second contact region and having a higher doping concentration than the drift region, wherein
carrier stop regions including the carrier stop region are discretely provided in a trench extending direction.

2. The semiconductor device according to claim 1, wherein
a lower end of the carrier stop region is located closer to the front surface of the semiconductor substrate than a lower end of the anode region.

3. The semiconductor device according to claim 1, wherein
a peak doping concentration of the carrier stop region is located closer to the front surface of the semiconductor substrate than a center of the anode region in a depth direction.

4. The semiconductor device according to claim 1, wherein
an upper end of the carrier stop region is in contact with a lower end of the second contact region.

5. The semiconductor device according to claim 4, wherein
second contact regions including the second contact region are discretely provided in a trench extending direction, and
the carrier stop region is provided below the second contact region.

6. The semiconductor device according to claim 5, wherein
a pitch between the carrier stop regions is 0.4 μm or more and equal to or smaller than a pitch between the second contact regions in a trench extending direction.

7. The semiconductor device according to claim 5, wherein
width of the carrier stop region is larger than width of the second contact region in a trench array direction.

8. The semiconductor device according to claim 7, wherein
the carrier stop region is provided apart from a side wall of a trench portion in a trench array direction.

9. The semiconductor device according to claim 5, wherein
the second contact region and the carrier stop region are provided extending from a side wall of a trench portion to a side wall of an adjacent trench portion in a trench array direction.

10. The semiconductor device according to claim 4, wherein
the second contact region is provided extending in a trench extending direction, and
the carrier stop regions are discretely provided below second contact regions including the second contact region extending.

11. The semiconductor device according to claim 10, wherein
width of the carrier stop region is larger than width of the second contact region in a trench array direction.

12. The semiconductor device according to claim 11, wherein
the carrier stop region is provided apart from a side wall of a trench portion in a trench array direction.

13. The semiconductor device according to claim 10, wherein
the second contact region and the carrier stop region are provided extending from a side wall of a trench portion to a side wall of an adjacent trench portion in a trench array direction.

14. The semiconductor device according to claim 1, wherein
a doping concentration of the carrier stop region is 1E16 cm⁻³ or more and 1E18 cm⁻³ or less.

15. The semiconductor device according to claim 1, wherein
a doping concentration of the second contact region is 1E18 cm⁻³ or more and 1E20 cm⁻³ or less.

16. The semiconductor device according to claim 1, wherein
the transistor portion includes a boundary region in direct contact with the diode portion, wherein
the boundary region includes:
the second contact region; and
the carrier stop region.

17. The semiconductor device according to claim 16, wherein
the transistor portion includes:
the drift region; and
a base region of the second conductivity type provided above the drift region and having a higher doping concentration than the anode region, and
the anode region is provided in the boundary region.

18. The semiconductor device according to claim 1, further comprising an interlayer dielectric film provided above the front surface of the semiconductor substrate, wherein
the interlayer dielectric film includes a contact hole provided above the second contact region, and width of the second contact region is equal to or larger than width of the contact hole in a trench array direction.

19. The semiconductor device according to claim 18, wherein
width of the carrier stop region is larger than the width of the contact hole in a trench array direction.

20. The semiconductor device according to claim 1, wherein
the semiconductor substrate is not provided with a lifetime control region including a lifetime killer.
